(19) United States
(12) Patent Application Publication
(10) Pub. No.: US 2012/0285667 A1
(43) Pub. Date: Nov. 15, 2012

(54) SOUND BAFFLING COOLING SYSTEM FOR LED THERMAL MANAGEMENT AND ASSOCIATED METHODS

(75) Inventors: Fredric S. Maxik, Indialantic, FL (US); Robert R. Soler, Cocoa Beach, FL (US); David E. Bartine, Cocoa, FL (US); Ran Zhou, Cape Canaveral, FL (US); Valerie A. Bastien, Melbourne, FL (US)

(73) Assignee: LIGHTING SCIENCE GROUP CORPORATION, Satellite Beach, FL (US)

(21) Appl. No.: 13/107,782

(22) Filed: May 13, 2011

(51) Int. Cl. H01L 23/467

(52) U.S. Cl. 165/121

(57) ABSTRACT

A cooling system for light emitting diodes (LEDs) is provided that may comprise acoustic baffle members, a micro-channel heatsink that includes fins adjacent to the LEDs, and a fluid flow generator adjacent to the micro-channel heatsink that directs a fluid in a flow direction. The fluid flow generator may include an input to receive the fluid and an exit to exhaust the fluid, which may contact a surface area of the fins. The sound emitted by the fluid flow generator may be substantially cancelled by the acoustic baffle members, which may reflect the sound to a source location as reflected sound waves defined by a substantially inverted phase.

### FIELD OF THE INVENTION

The present invention relates to the field of lighting devices and, more specifically, to active cooling systems for lighting devices that direct a fluid across fins of a heatsink.

### BACKGROUND OF THE INVENTION

As electronic devices operate, they may generate heat. This especially holds true with electronic devices that involve passing an electrical current through a semiconductor. As the amount of current passed through the electronic device may increase, so may the heat generated from the current flow.

In a semiconductor device, if the heat generated from the device is relatively small, i.e. the current passed through the semiconductor is low, the generated heat may be effectively dissipated from the surface area provided by the semiconductor device. However, in applications wherein a higher current is passed through a semiconductor, the heat generated through operation of the semiconductor may be greater than its capacity to dissipate such heat. In these situations, the addition of a heatsink may be required to provide further heat dissipation capacity.

Typically, a heatsink may provide an increased surface area from which heat may be dissipated. This increased heat dissipation capacity may allow a semiconductor to operate at a higher electrical current. Traditionally, a heatsink may be enlarged to provide increased heat dissipation capacity. However, increasing power requirements of semiconductor based electronic systems may still produce more heat than may be capably dissipated from a connected heatsink. Furthermore, continued enlargement of the heatsink size may not be practical for some applications.

The rapid development of high density power light emitting diode (LED) bulbs has created a challenge regarding effective thermal management. The common method of dissipating heat, as described in the prior art, involves using a traditional passive heatsink to cool electrically conductive semiconductors, such as LED semiconductors. However, in light of the continued development of high powered LED semiconductors, the heat flux of these LED semiconductors has risen significantly. As a result, the heat generated from the operation of high density power LEDs is quickly exceeding the dissipation capacity of traditional passive heatsinks to keep transistor junctions below maximum operating temperatures while remaining compact in size.

Therefore, there exists the need for a cooling system that provides adequate thermal management of semiconductor devices and, more specifically, LED semiconductors to keep the LED junction temperatures below the maximum operating temperatures in a compact form factor.

### SUMMARY OF THE INVENTION

The cooling system of the present invention may provide thermal management of semiconductor devices, advantageously keeping LED junction temperatures within acceptable operating levels while maintaining a compact form factor. Additionally, the cooling system of the present invention may advantageously allow a connected semiconductor device to operate at an elevated electrical current, providing additional operational capacity, i.e. brightness, from a smaller semiconductor package. Furthermore, through the effective cooling provided by the cooling system of the present invention, a connected electronic semiconductor device may beneficially have an increased operational life due to decreased thermal stress that may damage the connected semiconductor.

With the foregoing in mind, the invention is related to a cooling system that may advantageously provide enhanced cooling characteristics for LED devices. The cooling system may comprise acoustic baffle members, a micro-channel heatsink that includes fins adjacent to the LEDs, and a fluid flow generator adjacent to the micro-channel heatsink that directs a fluid in a flow direction. The fluid flow generator may include an input to receive the fluid and an exit to exhaust the fluid to contact a surface area of the fins. The sound emitted by the fluid flow generator may be substantially cancelled by the acoustic baffle members.

The sound may include source sound waves defined by a source phase and reflected sound waves defined by a reflected phase. Additionally, the acoustic baffle members may reflect the source sound waves to a source location as reflected sound waves. The source location may be proximately located at the exit of the fluid flow generator. The reflected phase may be substantially inverted from the source phase. Combining the source sound waves and the reflected sound waves may substantially cancel the sound emitted from the fluid flow generator.

The fluid may be exhausted from the exit in the flow direction as an impinging jet. The impinging jet may create static pressure to drive the fluid through the micro-channel heatsink. The fluid flow generator may be a piezoelectric diaphragm driving device. Additionally, the fluid may be a gaseous fluid.

The fins of the micro-channel heatsink may be separated by a gap having a width between about 0.1 millimeters and 4 millimeters. The fins may also be curved.

The fluid flow generator exit may be defined by an exit diameter. Additionally, a spacing may be included between the fins and the exit of the fluid flow generator. The spacing may proportionally be between about 4 and 5 times larger than the exit diameter.

The cooling system may include a filtration system. The filtration system may include a filter adjacent to the fluid flow generator that filters contaminants from the fluid. Alternately, the filtration system may control the flow direction of the fluid such that it is intermittently reversed. The standard flow direction may be defined by the fluid being received by the input and exhausted by the exit. Conversely, the flow direction that is reversed is defined by the fluid being received by the exit and exhausted by the input.

The acoustic baffle members may be adjacent to the LEDs. Alternately, the acoustic baffle members may be adjacent to the micro-channel heatsink. Also, the acoustic baffle members may be adjacent to an inside surface of a LED bulb holder.

A method aspect of the present invention is directed to actively cooling LED semiconductor. The method may include the steps of exhausting fluid from the exit in a flow direction to contact the fins and substantially canceling sound emitted by the fluid flow generator. The sound cancellation may be achieved by reflecting source sound waves to a source location as reflected sound waves. The source sound waves may be combined with the reflected sound waves.

The source sound waves may be defined by a source phase. Similarly, the reflected sound waves may be defined by a reflected phase. The reflected phase may be substantially inverted from the source phase. By combining the source sound waves and the reflected sound waves, the inverted phases may be added to substantially cancel the sound.

### BRIEF DESCRIPTION OF THE DRAWINGS

FIG. 1 is side elevation view of a cooling system according to the present invention.

FIG. 2 is a perspective view of a cooling system according to the present invention.

FIGS. 2A through 2E top plan views of fins, as configured in embodiments of the cooling system according to the present invention.

FIG. 3 is a perspective view of a fluid flow generator of a cooling system according to the present invention.

FIG. 4 is a top plan view of the fluid flow generator of FIG. 3.

FIG. 5 is a partial side elevation view of the fluid flow generator of FIG. 3.

FIG. 6 is a side elevation view of a fluid flow generator of a cooling system according to the present invention exhausting a fluid as an impinging jet.

FIG. 7 is a side elevation view of a fluid flow generator of a cooling system according to the present invention exhausting a fluid as an impinging jet across fins.

FIG. 8 is a perspective view of the fins configured as pins according to an embodiment of the present invention.

FIG. 9 is a side elevation view of acoustic baffle members according to an embodiment of the present invention.

FIG. 10 is a side elevation view of acoustic baffle members according to an embodiment of the present invention.

FIGS. 11A through 11D are waveform diagrams illustrated the phase of sound related to the sound canceling operation of the present invention.

FIG. 12 is a flow chart detailing heat dissipation using the active cooling system of the present invention.

FIG. 13 is a flowchart detailing filtering the fluid using the active cooling system of the present invention.

FIG. 14 is a perspective diagram of a flow developing chamber according to an embodiment of the active cooling system of the present invention.

### DETAILED DESCRIPTION OF THE PREFERRED EMBODIMENT

The present invention will now be described more fully hereinafter with reference to the accompanying drawings, in which preferred embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Those of ordinary skill in the art realize that the following descriptions of the embodiments of the present invention are illustrative and are not intended to be limiting in any way. Other embodiments of the present invention will readily suggest themselves to such skilled persons having the benefit of this disclosure. Like numbers refer to like elements throughout.

In this detailed description of the present invention, a person skilled in the art should note that directional terms, such as “above,” “below,” “upper,” “lower,” and other like terms are used for the convenience of the reader in reference to the drawings and the accompanying descriptions. Also, a person skilled in the art should notice this description may contain other terminology to convey position, orientation, and direction without departing from the principles of the present invention.

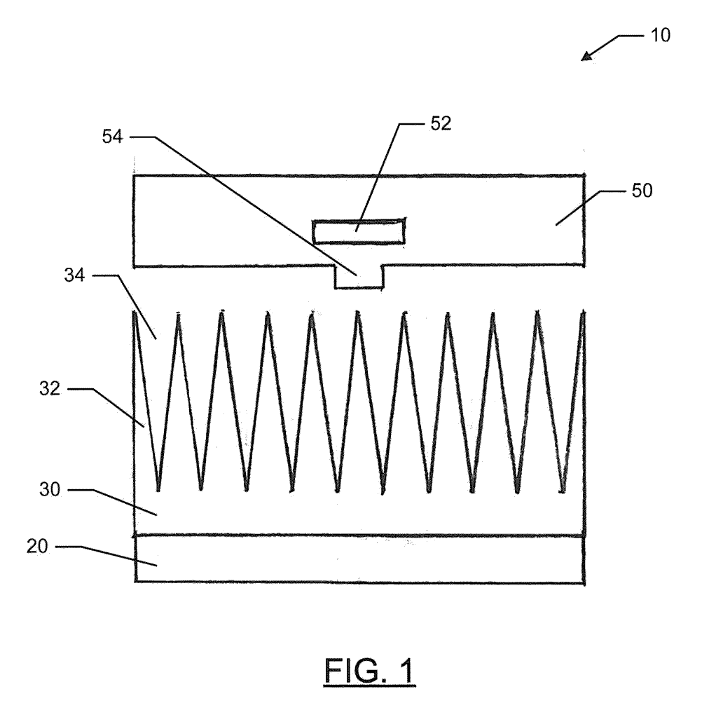

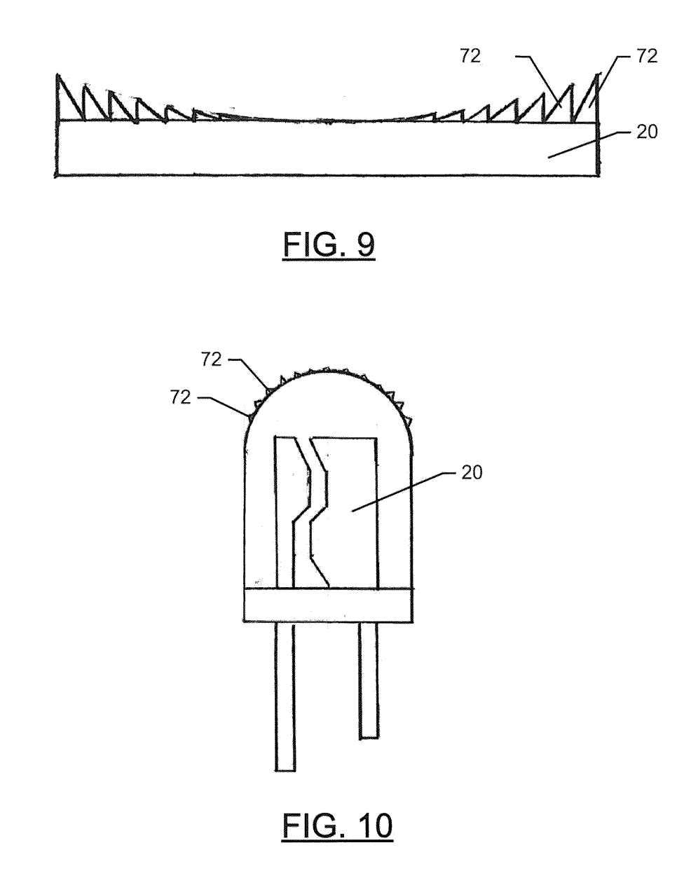

Referring now to FIGS. 1-15, a cooling system 10 according to the present invention is now described in greater detail. Throughout this disclosure, the cooling system 10 may also be referred to as the system, the device, or the invention. Alternate references of the cooling system 10 in this disclosure are not meant to be limiting in any way.

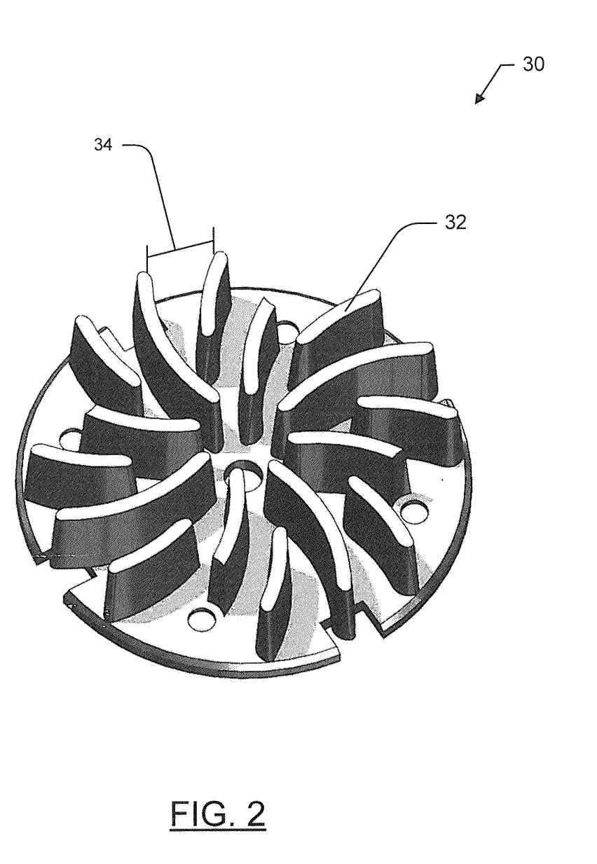

As perhaps best illustrated in FIG. 1, the cooling system 10 according to an embodiment of the present invention may be defined as a device including a micro-channel heatsink 30, fluid flow generator 50, and acoustic sound baffle members 72. These general components may be located adjacent to an electronic semiconductor device, such as a light emitting device (LED) semiconductor 20, or any heat generating element. The fluid flow generator 50 may further include an input 52 and an exit 54, which may otherwise be referred to as an input port and nozzle exit, respectively, as illustrated in FIGS. 1, 3, and 4 through 7, and the accompanying description. The micro-channel heatsink 30 may further include fins 32 and gaps 34, as illustrated in FIGS. 1, 2, 2A -2E, 7, and 8, and the accompanying description.

In the following description, the micro-channel heatsink 30 may be described more generally as a heatsink 30. A person of skill in the art will appreciate that a micro-channel heatsink 30 may be a subset of heatsinks 30 and may be referenced in the following disclosure for clarity purposes, without the intent to limit the present invention in any way. Similarly, the fluid flow generator 50 may be described more specifically as a micro-blower. A person of skill in the art will appreciate that a micro-blower may be a subset of fluid flow generators 50 and that the term is used in the following disclosure for clarity purposes, without the intent to limit the present invention in any way.

A person of skill in the art will appreciate, after having the benefit of this disclosure, that although the following describes the use of the cooling system 10 of the present invention as dissipating heat for an electrically conductive LED semiconductor 20, the disclosed invention may be used to dissipate heat from virtually any heat generating source such as, for example, microprocessors, integrated controllers, or transformers.

As illustrated, for example, in FIG. 1, the micro-channel heatsink 30 may be physically located adjacent to an LED semiconductor 20. More specifically, in an embodiment of the present invention, the micro-channel heatsink 30 may be attached to the LED semiconductor 20. However a person of skill in the art will appreciate additional connective configurations included within the scope and spirit of the present invention.

In an embodiment of the present invention, a thermally conductive material may be placed between the micro-channel heatsink 30 and the LED semiconductor 20. Inclusion of a thermally conductive material may enhance the thermal conductive efficiency of the aforementioned adjacently located components. Presented as a non-limiting example, the thermal conductive material may be a thermal paste based on ceramic, metallic, carbon, or silicone based materials.

The inclusion of a thermally conductive material applied between the LED semiconductor 20 and the micro-channel heatsink 30 may provide an enlarged surface area in which the LED semiconductor 20 may contact the micro-channel heatsink 30. The enlarged contact surface area may be created by filling rogue air pockets and surface abnormalities typically present on the surfaces of a LED semiconductor 20 and/or heatsink 30. The thermally conductive materials may provide heat transfer efficiency thousands of times greater than that of air.

As a result, the inclusion of thermally conductive materials between the adjacent location of the LED semiconductor 20 and the micro-channel heatsink 30, which may be components of the cooling system of the present invention, may advantageously allow the system to conduct a substantially increased amount of heat generated by the adjacently located LED semiconductor 20 during its operation. A person of skill in the art will also appreciate additional embodiments that may lack the application of the thermally conductive material between the LED semiconductor 20 and the micro-channel heatsink 30 to be included within the scope of the present invention.

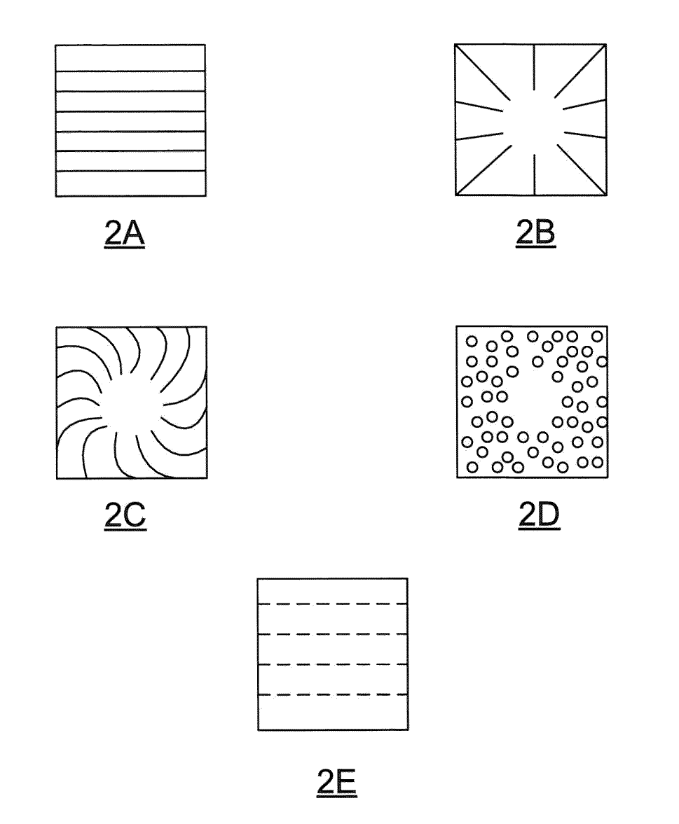

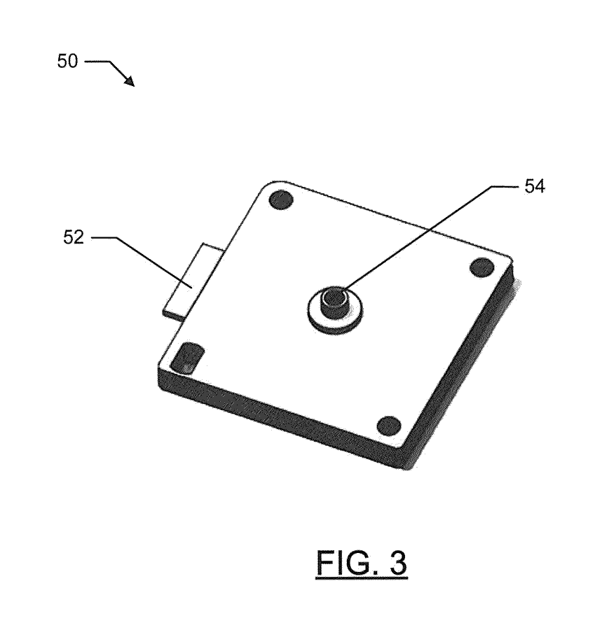

As further illustrated in FIG. 1, a fluid flow generator 50 may be located adjacent to the micro-channel heatsink 30. More specifically, in an embodiment of the present invention, the fluid flow generator 50 may be attached to the micro-channel heatsink 30 by a connector such as an adhesive, latch, spring, screw, or other connection known within the art. Preferably, the fluid flow generator 50 may be located adjacent to the micro-channel heatsink 30 such to allow the exhaust of a fluid, which may be a gas such as air, for example, across the surface area provided by the micro-channel heatsink 30. Such fluid may be received by the input 52 of the fluid flow generator 50 and exhausted from the exit 54, as will be discussed further in relation to FIGS. 3 and 4.

For clarity, a micro-blower may be described in this disclosure as a specific example of a fluid flow generator 50. A person of skill in the art will appreciate, after having the benefit of this disclosure, that although a micro-blower may be specifically described within this disclosure, any fluid flow generating device may be used to generate the flow of a fluid across the surface area of a micro-channel heatsink 30. Additionally, for clarity, the following disclosure may discuss using air as a specific example of a fluid being exhausted from the micro-blower and flowing across the micro-channel heatsink 30. A person of skill in the art, however, will appreciate that any fluid may flow across the surface area of the micro-channel heatsink 30 within the scope of the present invention. Non-limiting examples of additional fluids included within the scope of the present invention may include gases, liquids, or other states of matter with flowing properties.

Referring now to FIG. 2, additional features of the cooling system 10 of the present invention will now be discussed in greater detail. More specifically, the micro-channel heatsink 30, which may be referred to generally as the heatsink 30, will now be discussed. Traditionally, a heatsink 30 is a component used to assist in the dissipation of heat crated by an adjacent heat generating element. A heatsink 30 may typically enhance the amount of heat dissipated by providing an enlarged surface area that may be greater than otherwise solely provided by the heat generating element. As a fluid, such as air, may flow across the surface area of the heatsink 30, the heat may be transferred from the surface area of the heatsink 30 to the fluid.

The micro-channel heatsink 30 of the cooling system of the present invention may include a number of fins 32. These fins 32 may be configured to provide a larger surface area than may otherwise be provided solely by the surface of the heat generating element. As would be understood by a person of skill in the art, the fins 32 may be configured in a variety of heights, shapes, and positions. Examples of such various configurations of the fins 32, provided without the intent to be limiting, may include parallel rows (FIG. 2A), planes fanned from a center location (FIG. 2B), curved arrays (FIG. 2C), staggered pins (FIG. 2D), segmented rows (FIG. 2E), or numerous additional configurations that may provide an adequate surface area for the desired heat dissipation properties. A skilled artisan, after having the benefit of this disclosure, will appreciate additional configurations of fins 32 that allow the dissipation of heat through an enlarged surface area that exists within the scope and spirit of the present invention.

A gap 34 may exist between each fin 32 of the micro-channel heatsink 30. The gap 34 may provide a channel for the flow of a fluid between the fins 32. Flow of the fluid may be generated by a fluid flow generator 50, such as a micro-blower, which will be further discussed below. Since many electronic components may be very small, with dimensions relative to approximately a micrometer scale, the gaps 34 between the fins 32 may be spaced relative to the same scale. Preferably, the fins. 32 are positioned such that the gaps 34 between each fin 32 may be between 0.1 and 4 millimeters. However, a person of skill in the art, after having the benefit of this disclosure, will appreciate that gaps 34 of any width may be located between the fins 32 of the micro-channel heatsink 30 such to allow the flow of fluid between the fins 32. Furthermore, a skilled artisan will appreciate that a gap 34 between fins 32 need not be defined by a constant width, and may include variable widths, such as with fins 32 that are curved or axially extended from the center of the micro-channel heatsink 30.

Due to the small footprint of the fins 32 and narrow spacing of the gaps 34, as may they may exist in some embodiments, a pressure drop may form within the micro-channel heatsink 30. In embodiments of the present invention, the fins 32 may be aligned to extend from a central location on the heatsink 30 in an axially, curved, or helically spiraled configuration, which configurations would be appreciated by a person of skill in the art, to provide the surface area necessary for sufficient heat dissipation.

In some fin 32 configurations, such as those provided in the example above, a fluid contained within the center of the fin 32 configuration may flow toward the area outside of the fin 32 envelope. This outward flow may be especially likely to occur in configurations wherein the fins 32 and the gaps 34 may be measured on approximately a micrometer scale. The aforementioned outward flow may occur as the adhesive forces of the fluid may dominate over its cohesive forces through capillary action, as would be understood by a person of skill in the art. The capillary action may cause the fluid to pass through each micro-channel gap 34. The fluid may then be channeled away from the center of the heatsink 30, which may cause the pressure inside the heatsink 30 to decrease.

The presence of a low pressure region may inhibit the efficiency of the heat dissipation provided by the micro-channel heatsink 30. The decreased efficiency may be due to flow viscosity friction and a decreased density of fluid to which the heat may be transferred. To overcome the negative effects of the low pressure region, a positive pressure may be applied to the region. Such positive pressure may be generated by a fluid flow generator 50 or, more specifically, a micro-blower 50.

An example of a pressure drop that may be present in micro-channel heatsink 30, as included in the cooling system 10 of the present invention, will now be provided with the intent not to limit the present invention. The example includes an embodiment that may further include a micro-channel heatsink 30 with fins 32 measuring 300 micrometers in width. The gap 34 located between the fins 32 may also measure 300 micrometers in width. In this example, the jet flow of air may be the working fluid impinging on the fins from flow generator exit at 25 meters per second. The passing of air may create a pressure drop of 1672.5 Pascal along a 10 millimeter heat skin length, as would be understood by a person of skill in the art. As a result, to efficiently force a fluid such as air across the fins 32 of the micro-channel heatsink 30, a fluid flow generator 50 may be required to create a static pressure greater than 1672.5 Pascal.

Referring now additionally to FIG. 3-5, additional features of the cooling system 10 of the present invention will now be discussed in greater detail. More specifically, the fluid flow generator 50, which may additionally be herein referred to as the micro-blower, will now be discussed. A fluid flow generator 50 may be defined as any device capable of receiving a fluid from one location and exhausting the fluid from a second location.

As illustrated in FIGS. 3 and 4, the fluid flow generator 50 may include an input 52 and exit 54, which may be otherwise referred to as an input port and nozzle exit, respectively. Generally, the fluid flow generator 50 may receive a fluid from the input 52. Through the operation of the fluid flow generator 50, the fluid may then be exhausted from the exit 54. As a result, the fluid may flow in a flow direction from the input 52, through the fluid flow generator 50, and exhausting from the exit 54.

The fluid flow generator 50, and more specifically the input 52 and the exit 54 of the fluid flow generator 50, will now be discussed greater detail. As previously stated, the fluid flow generator 50 may generate a flow of fluid in the fluid flow direction. The fluid flow direction is typically defined as a fluid being received by the input 52 and exhausted by the exit 54.

In an embodiment of the present invention, such as the embodiment illustrated in FIG. 3, the input 52 may be located on the side of the fluid flow generator 50. However, a person of skill in the art will appreciate, after having the benefit of this disclosure, that the input may be located at any position that may allow it to receive a fluid. Additionally, an exit 54 may located on the bottom face of the fluid flow generator 50, positioned such to direct the flow of fluid to a desired location. However, a person of skill in the art will appreciate, after having the benefit of this disclosure, that the exit may be located at any position that may allow the exhaust of a fluid. The flow of the fluid in the fluid flow direction may be enabled by the operation of the fluid flow generator 50, and more specifically, a micro-blower such as but not limited to a piezoelectric diaphragm device.

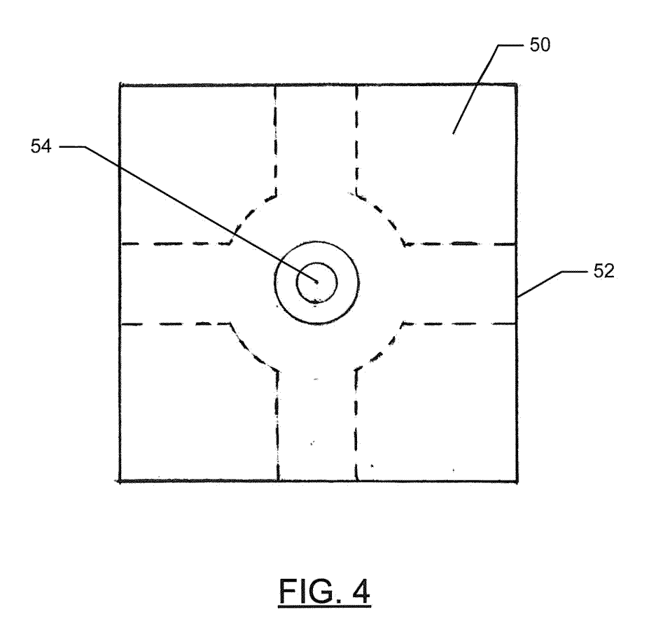

In an embodiment of the cooling system 10 of the present invention, as perhaps best illustrated in FIG. 5, the fluid flow generator 50 may be a piezoelectric diaphragm driving device. The structure and function of a piezoelectric diaphragm driving device may be implied by its name. “Piezo” is derived from the Greek root meaning to squeeze or press. “Electric” is commonly used within the English language and may relate to the flow of electrons. A “diaphragm,” as it may relate to mechanical applications, may define a sheet of semi-flexible material that may bisect and modulate the pressure contained within a volume via vibration and/or oscillation.

Thus, as implied by its name, a piezoelectric diaphragm device may cause the compression and expansion of a connected diaphragm 56 when an electrical current is applied to the device. As the input electrical current may change, such as for example, with an alternating current (AC) source, the piezoelectric diaphragm 56 may alternate between compressive and expansive states. When applying an oscillating current to the piezoelectric diaphragm device, the diaphragm 56 of the device may also oscillate.

The oscillation of the diaphragm 56 within the device may cause the volume of an interior chamber 58 to change with respect to the compressive or expansive state of the diaphragm 56. This change in interior volume may cause the pressure of the fluid contained within the interior chamber 58 to change as well. For example, when the diaphragm 56 is expanded or compressed such to increase the volume of the interior chamber 58, fluid may be received by the interior chamber 58 of the piezoelectric diaphragm device in response to the decreased pressure created within the chamber. Conversely, when the diaphragm 56 is compressed or expanded such to decrease the volume of the interior chamber 58, fluid may be exhausted from the interior chamber of the piezoelectric diaphragm device in response to the increased pressure created within the chamber.

In configurations of the micro-channel heatsink 30 that may form a low pressure region, as discussed above, the exit 54 may be orientated such to direct the flow of a fluid to the low pressure region. As the fluid is directed to the low pressure region, the density of fluid included within the region may increase, thereby creating an elevated static pressure. The static pressure generated may be sufficient to pass a large amount fluid through the gaps 34, which may be located between the fins 32 of the heatsink 30.

In an embodiment of the present invention, the static pressure created by the fluid flow generator 50 may be as high as 2000 Pascal. However, a person of skill in the art, after having the benefit of this disclosure, will appreciate that an alternately configured fluid flow generator 50 may be capable of exhausting fluid with pressure characteristics other than the 2000 Pascal of the illustrative embodiment presented above.

The pressure difference may create a flow of fluid with a fluid density sufficient to accept the heat radiated from the micro-channel heatsink 30. The heat from the heatsink 30 may be exchanged from the surface area of the fins 32 to the passing fluid. The heated fluid may then be exhausted away from the micro-channel heatsink 30 as additional fluid may be forced through the gaps 34 of the heatsink 30.

The amount of heat dissipated by the cooling system 10 of the present invention may be relative to of the surface area provided by the fins 32 and the amount of fluid passed across that surface area. To further enhance the heat dissipation characteristics of the present invention, the cooling system 10 may increase the amount of fluid passed across a surface area, the surface area to which fluid may be flowed across, or both.

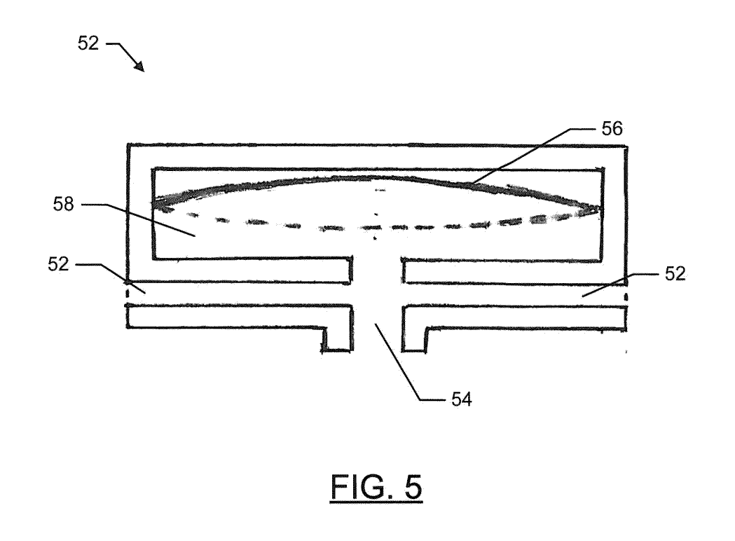

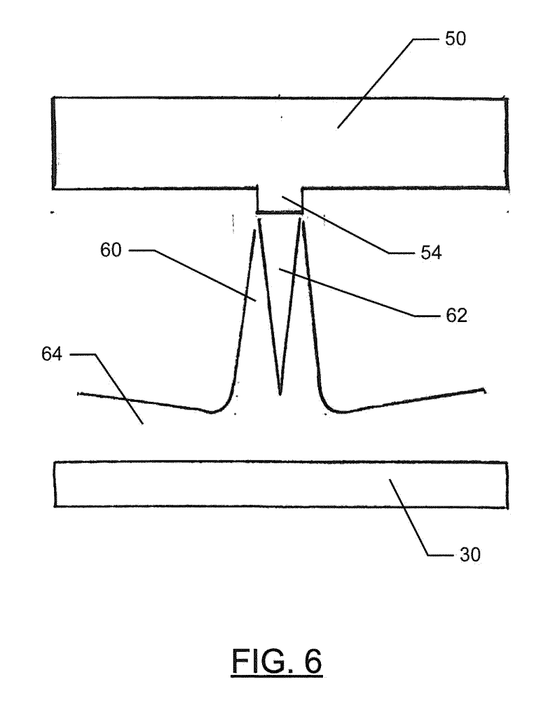

To provide enhanced flow characteristics by increasing the amount of fluid that may flow across the heatsink 30, the fluid may be exhausted from the exit 54 as an impinging jet 60, which may be best illustrated in FIGS. 6 and 7. An impinging jet 60 defines a fluid flow pattern that may include a central core 62 and an approximately horizontal plane 64 of flowing fluid. If improperly calibrated, the impinging jet 60 may also include a number of vortexes or toroidal patterns that could negatively affect the flow characteristics of the fluid. The inclusion of vortexes and recirculating toroidal patters may result in a reduction in local heat transfer coefficients by up to fifty percent.

As perhaps best illustrated in FIG. 7, the horizontal plane 64 of the impinging jet 60, as implied by the name, may force a high velocity flow of fluid to impinge upon the fins 32 of the heatsink 30. Since the fluid may flow at a high velocity, a substantial amount of fluid may be forced across the fins 32. Given that the heat may be dissipated from the fins 32 of the micro-channel heatsink 30 to the fluid, an increased amount of fluid contacting the surface area of the fins 32 may advantageously result in an increased amount of heat dissipated from the fins 32 to the fluid. In applications that use an impinging jet 60 of a gaseous fluid, such as air, cooling performance may beneficially approximate or surpass that of traditional liquid cooling solutions.

In an embodiment of the cooling system 10 of the present invention, the dimensions of the fluid flow generator 50, and more specifically the micro-blower, may be designed in relation to the micro-channel heatsink 30. By having relative dimensions, the fluid flow generator 50 and the micro-channel heatsink 30 may together achieve a high cooling efficiency. Such relationship may include a spacing configured between the fins 32 of the micro-channel heatsink 30 to that is proportional the diameter of the exit 54 to eliminate disruptive fluid flow patterns, such as vortexes or toroidal recirculation.

Preferably, the spacing may be approximately four to five times larger than diameter of the exit 54 to minimize the decline in fluid flow efficiency that may be created by disruptive flow patterns due to an improperly calibrated impinging jet 60. Additionally, the height of the fins 32 may be proportionally configured with regard to the spacing and/or exit 54 diameter to further define the flow characteristics of fluid exhausted as an impinging jet. However a person of skill in the art will appreciate additional proportional configurations resulting in minimization of fluid flow interference included within the scope and spirit of the present invention.

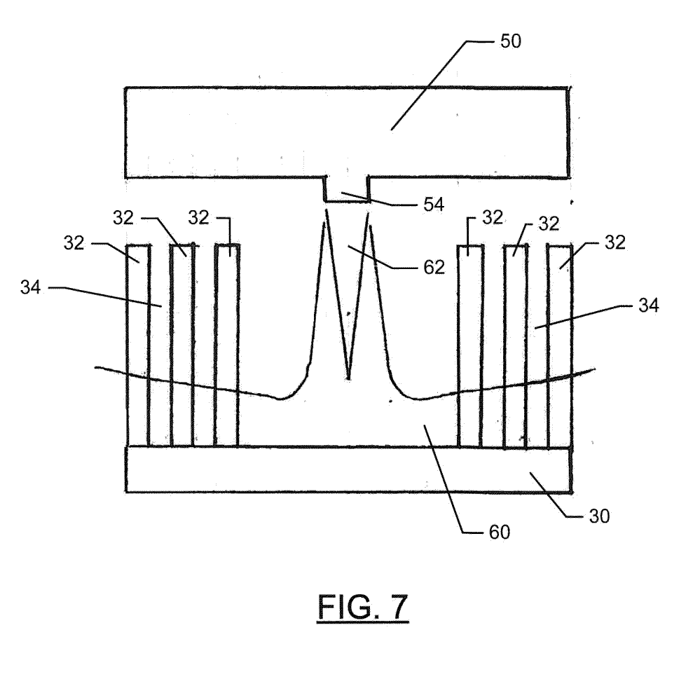

Additionally, to provide enhanced flow characteristics through increased fluid flow across the heatsink 30, the surface area of the heatsink 30 may be increased, which may be best illustrated in FIGS. 2A through 2E, and FIG. 8. The surface area of the heatsink 30 may be increased by altering the shape and configuration of its fins 32. In an embodiment of the present invention, as perhaps best illustrated in FIG. 2, the fins 32 may be curved to provide additional surface area. This curved fins 32 may, for example but not limited to, be curved in a helical pattern to minimize interference with the flow patterns created by a fluid flow generator, such as, for example, with an impinging jet 60.

In an additional embodiment of the present invention, as perhaps best illustrated in FIG. 8, the fins 32 may be configured as an array of pins 36. In this embodiment, the fins 32 may include additional segmentation, each segment of the fins 32 being defined as pins 36. An additional gap 34 may be located between each pin 36 to provide an additional surface area from which heat may be dissipated. A person of skill in the art will appreciate additional embodiments wherein inclusion of pins 36 may be combined with multiple additional fin 32 configurations to enhance the surface area of the heatsink 30, such as, but not limited to, segmenting curved fins 32 into pins 36.

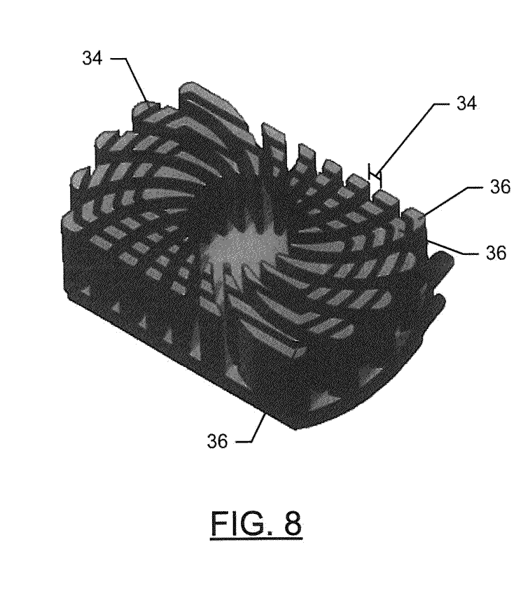

Referring now additionally to FIGS. 9-11, additional features of the cooling system of the present invention are now discussed in greater detail. More specifically, the acoustic sound baffle members 72 of the cooling system 10 will now be discussed. As the cooling system 10 of the present invention operates, an audible sound may be produced. In some applications of the present invention, this sound may be undesired. To remedy this undesired condition, acoustic sound baffle members 72 may be provided to cancel the unwanted sound.

The sound generated by the cooling system 10 may originate from a source location. Movement or oscillation involved with the operation of the fluid flow generator 50 may create a sound as it operates. As a result, the source location may be the proximately located at the exit 54 of the fluid flow generator 50. A person of skill in the art, however, will appreciate that sound may originate from a number of locations within the cooling system 10 of the present invention, which locations may also be defined as source locations, and to which the sound originated therefrom may also be cancelled.

The acoustic baffle members 72 may include a plurality of sound reflective surfaces that may reflect the sound back to the source location. The sound reflective surfaces, which may be configured with an angular orientation and distance, calculated with respect to the source location to provide sound cancellation. The operation of sound cancellation will be discussed further below.

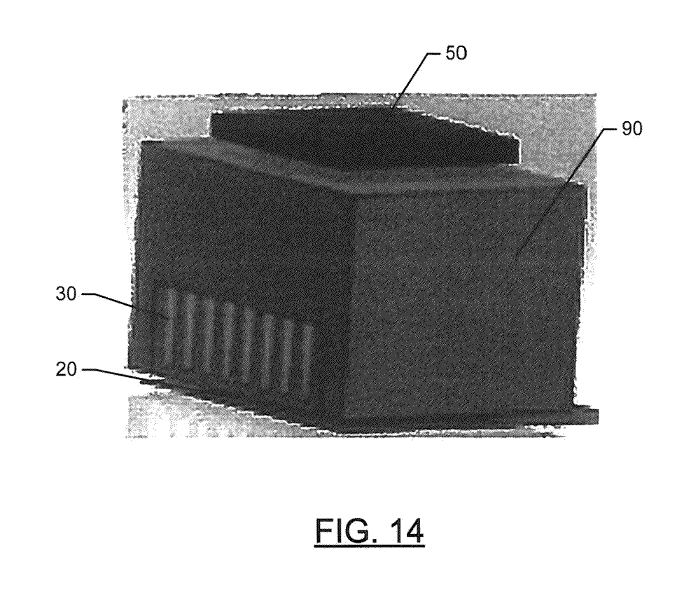

The acoustic baffle members 72 may be located in any location such that sound may be reflected back to the source location. Such location of the acoustic baffle members 72 may include, but should not be limited to, the surface of the micro-channel heatsink 30 or its corresponding fins 32, an enclosure that may surround the micro-channel heatsink 30 and/or fluid flow generator 50, a flow developing chamber 90 (FIG. 14) that may secure and position a LED semiconductor 20, or the LED semiconductor 20 itself. A person of skill in the art, after having the benefit of this disclosure, will appreciate that the acoustic baffle members 72 may be located at any position wherein sound may be reflected to its source location, and thus should not limit the location of the acoustic baffle members 72 to the preceding examples.

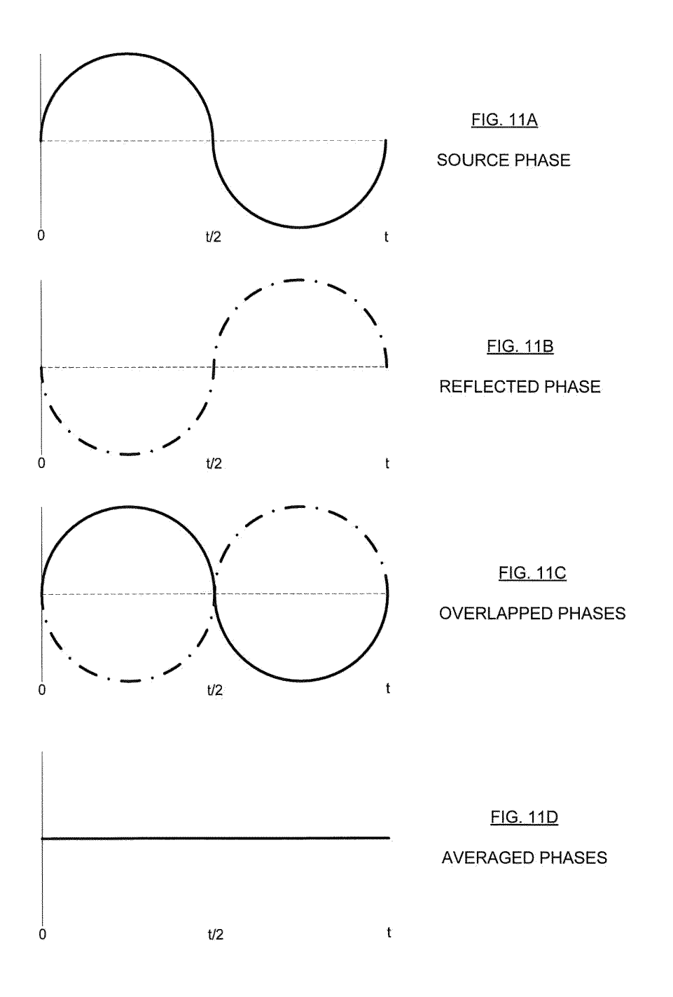

As perhaps best illustrated in FIGS. 11A-D, the sound to be cancelled by the acoustic baffle members 72 may include sound waves, as would be apparent to a person of skill in the art. For clarity in the foregoing description, the sound waves included in the sound originated from the source location may be herein referred to as source sound waves. The source sound waves may further be defined by a source phase, or an offset of the beginning of each period of the source sound wave from zero. The source phase may be best illustrated in FIG. 11A. For simplicity in the foregoing description, the source phase will be assumed as the reference phase and defined at zero degrees. A person of skill in the art, after having the benefit of this disclosure, will appreciate that the source phase could be defined as any phase value within the scope of the invention, and that the use of zero degrees for the source phase herein is provided solely for the clarity of this disclosure.

The sound reflected by the acoustic baffle members may also include sound waves, as would be apparent to a person of skill in the art. For clarity in the foregoing description, the sound waves reflected from the acoustic baffle members may be herein referred to as reflected sound waves. The reflected sound waves may further be defined by a reflected phase, or an offset of the beginning of each period of the reflected sound wave from zero. The reflected phase may be best illustrated in FIG. 116. For simplicity in the foregoing description, and with respect to defining the source phase as zero degrees, the reflected phase will be assumed as being directly inverted from the source phase, defined as 180 degrees. A person of skill in the art, after having the benefit of this disclosure, will appreciate that the reflected phase could be defined as any phase value within the scope of this invention, and that the use of 180 degrees for the reflected phase herein is provided solely for the clarity of this disclosure.

As previously described, the sound reflective surfaces of the acoustic baffle members 72 may be configured to reflect the sound in the direction of the source location such that the reflected sound wave may overlap the source sound waves. To achieve maximum sound cancellation efficiency, it is desired for the reflected phase of the reflected sound wave to be approximately inverted from the source phase of the source sound wave. This overlap may perhaps be best illustrated in FIG. 11C. Due to the additive properties of waves, and more specifically the additive properties of sound waves, the source and reflected sound waves with approximately inverted phases may effectively add to zero, as perhaps best illustrated in FIG. 11D. As a result, the sound defined by the source sound waves may be negated by the added corresponding inverted and reflected sound wave, advantageously achieving sound cancellation.

Additional features of the cooling system of the present invention are now discussed in greater detail. More specifically, a filtration system used to remove contaminates from a fluid will now be discussed. Contaminates may be any unwanted moisture, fluid, or particle that may interfere with the cooling efficiency of the cooling system 10 of the present invention. Such interference may be caused by blocking or restricting the flow of the fluid across the fins 32 of the micro-channel heatsink 30. To prevent the loss of efficiency that may occur from the presence of contaminates, the cooling system 10 of the present invention may include a filtration system to remove such contaminates.

In an embodiment of the cooling system 10 of the present invention, a filtration system may control and alternate the fluid flow direction during the operation of the cooling system 10. Alteration of the fluid flow direction, such as but not limited to reversing the fluid flow direction, may occur at different periods during operation of the cooling system 10 of the present invention. The reversal of the fluid flow direction may be defined as receiving the fluid from the exit 54 and exhausting the fluid from the input 52.

As will be understood by a person of skill in the art, the period in which the flow direction is altered need not be confined to occur within any predetermined instance or duration. With the foregoing being said, the alteration or reversal of the fluid flow direction may occur initially, periodically, intermittently, randomly, and/or terminally, and remain within the scope and spirit of the present invention.

The reversal of the fluid flow direction may reduce the amount of contaminates in the fluid by directing the contaminants in the reversed flow direction. This may loosen or dislodge any contaminants that may be positioned against a surface of the micro-channel heatsink 30, such as the fins 32. The use of a reversed fluid flow direction may also dislodge any contaminants that have become wedged within the gaps 34 between the fins 32. After period of time in which the fluid flow generator 50 has operated in the reversed flow direction expires, the fluid flow generator 50 may then direct fluid in the flow direction defined as receiving the fluid from the input 52 and exhausting the fluid from the exit 54.

In an additional embodiment of the filtration system, a filter may be used to trap contaminants before they may enter the micro-channel heatsink 30. The filter may include a woven mesh of fiber or other material, sufficiently configured to trap particles that may flow through the filter. The filter may be a nanometer filter, or a filter that may be comprised from materials and patterns that are interwoven on the nanometer scale.

The filter may be positioned in any location wherein contaminates may be intercepted and removed from the fluid before reaching the micro-channel heatsink 30. Such locations may include, but should not be limited to, adjacent to the input 52, adjacent to the exit 54, or at any location wherein a fluid is drawn that will flow across the micro-channel heatsink 30. The filter may include, but does not require, the ability to be replaced replacement filters.

The cooling system 10 of the present invention may provide advanced performance cooling semiconductor devices, such as high current LEDs. The enhanced heat dissipation capability of the cooling system 10 of the present invention advantageously allows a semiconductor device to operate at with a higher electrical current input, while providing enhanced efficiency and longevity of the from the semiconductor device.

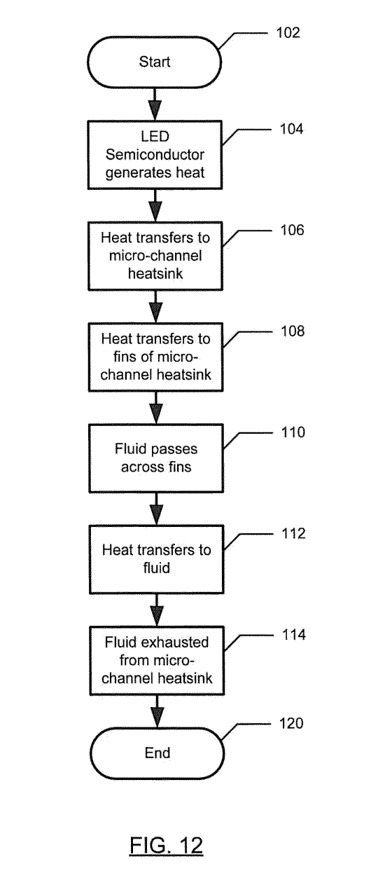

Referring now to flowchart 100, as illustrate in FIG. 12, an illustrative process of generating and dissipating heat in accordance with embodiments of the present invention will now be discussed. Starting at Block 102, the LED semiconductor 20 may generate heat during its operation (Block 104). A person of skill in the art will appreciate that although an LED semiconductor 20 is used in the present example, the cooling system 10 of the present invention may be used to dissipate the heat away from any device that may generate heat during its operation.

The heat generated from the LED semiconductor 20 may then transfer to the micro-channel heatsink 30 (Block 106). As previously discussed, a thermally conductive material may be located between the heat generating semiconductor and the micro-channel heatsink 30 to further increase heat transfer efficiency. Once the heat has been transferred to the micro-channel heatsink 30 at the point adjacent to the heat generating semiconductor, the heat may be further transferred to the fins 32 of the micro-channel heatsink 30 (Block 108).

A fluid may then pass across the fins 32 of the micro-channel heatsink 30 (Block 110). As previously discussed, this fluid may be forcibly passed across the fins 32 as the fluid may be exhausted from a fluid flow generator 50. Additionally, as previously discussed, the fluid may be passed across the fins 32 at a high velocity from an impinging jet 60. As the fluid passes across the fins, heat may transfer to the fluid from the fins 32 (Block 112). As previously discussed, an increased surface area provided by the fins 32 may allow for an increased amount of heat to be transferred to the fluid.

As the fluid continues to be forced through across the fins 32, the fluid may be exhausted from the micro-channel heatsink 30 (Block 114). As the fluid is exhausted, so is the heat that has been transferred to the fluid. Exhausting of the heated fluid ends the heat dissipation process as it may be performed by the cooling system 10 of the present invention (Block 120).

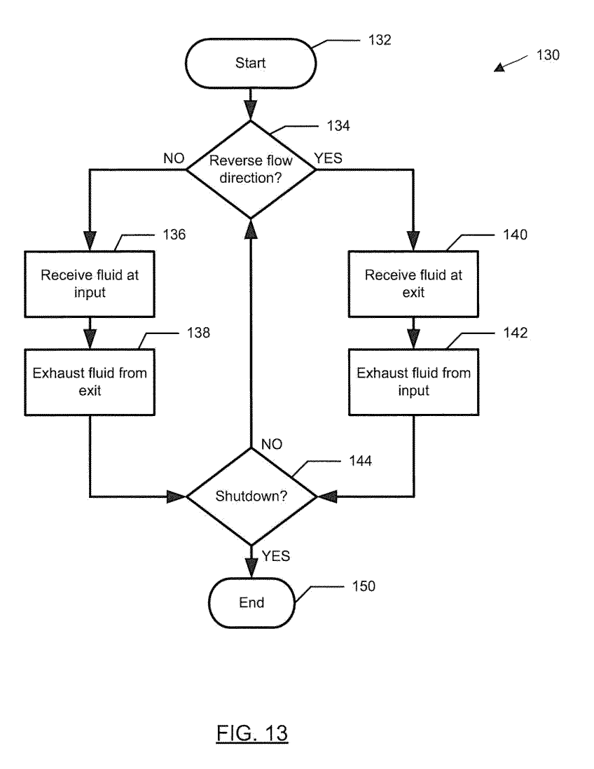

Referring now to flowchart 130, as illustrated in FIG. 13, an illustrative process of reversing the flow direction of fluid, as produced by the fluid flow generator 50, or more specifically a micro-blower, in an embodiment of the filtration system of the present invention, will now be discussed. Starting at Block 132, the cooling system 10 may determine if whether to reverse the flow direction of the fluid (Block 134). If the fluid flow generator 50 will not reverse the flow direction of the fluid, the fluid flow generator 50 may receive a fluid from its input 52 (Block 136). The fluid flow generator 50 may then exhaust the fluid from the exit 54 (Block 138). The flow of fluid may be generated by a pumping means, such as previously described above, as for example by a piezoelectric diaphragm device.

If the cooling system 10 determines at the operation described at Block 134 that the flow direction of the fluid should be reversed, the fluid flow generator 50 may receive a fluid from its exit 54 (Block 140). The fluid flow generator 50 may then exhaust the fluid from it input 52 (Block 142).

After flowing the fluid in either the forward or reversed flow direction for a duration, the cooling system 10 of the present invention may determine whether a shutdown command has be received (Block 144). If no shutdown command has been received, the cooling system 10 may return to the operation described in Block 134, wherein it may again determine whether to reverse the flow direction. If a shutdown command has been received, the operation may be terminated at Block 150.

In an embodiment of cooling system of the present invention, as perhaps best illustrated in FIG. 14, a flow developing chamber 90 may be included to enhance the flow patterns of fluid as it may pass across the micro-channel heatsink 30. Additionally, the flow developing chamber 90 may partially enclose the micro-channel heatsink 30, which may advantageously reduce the amount of contaminates that my come into the fins 32 and gaps 34 of the micro-channel heatsink 30.

The flow developing chamber 90 may be located adjacent to the micro-channel heatsink 30. The flow developing chamber 90 may additionally be located adjacent to the fluid flow generator 50. In some applications of the present embodiment, the flow developing chamber 90 may be positioned such that it encloses a portion of the micro-channel heatsink 30, while being adjacently located between the heatsink 30 and the fluid flow generator 50.

Many modifications and other embodiments of the invention will come to the mind of one skilled in the art having the benefit of the teachings presented in the foregoing descriptions and the associated drawings. Therefore, it is understood that the invention is not to be limited to the specific embodiments disclosed, and that modifications and embodiments are intended to be included within the scope of the appended claims.

What is claimed is:

1. A cooling system for light emitting diodes (LEDs), comprising:
acoustic baffle members;
a micro-channel heatsink that includes fins adjacent to the LEDs; and
a fluid flow generator adjacent to the micro-channel heatsink that directs a fluid in a flow direction, the fluid flow generator including an input to receive the fluid and an exit to exhaust the fluid to contact a surface area of the fins;
wherein sound emitted by the fluid flow generator is substantially cancelled by the acoustic baffle members.

2. A system according to claim 1 wherein the sound includes source sound waves defined by a source phase; and wherein the acoustic baffle members reflect the sound to a source location as reflected sound waves defined by a reflected phase.

3. A system according to claim 2 wherein the reflected phase is substantially inverted from the source phase; and wherein combining the source sound waves and the reflected sound waves substantially cancels the sound emitted from the fluid flow generator.

4. A system according to claim 2 wherein the source sound waves originate from the source location that is proximately located to the exit of the fluid flow generator.

5. A system according to claim 1 wherein the fluid is exhausted from the exit in the flow direction as an impinging jet.

6. A system according to claim 5 wherein the impinging jet creates static pressure to drive the fluid through the micro-channel heatsink.

7. A system according to claim 1 wherein the fluid is gaseous.

8. A system according to claim 1 wherein the fluid flow generator is a piezoelectric diaphragm driving device.

9. A system according to claim 1 wherein the fins of the micro-channel heatsink are each separated by a gap having a width between about 0.1 millimeters and 4 millimeters.

10. A system according to claim 1 wherein the fins are curved.

11. A system according to claim 1 wherein the fluid flow generator exit is defined by an exit diameter; wherein a spacing is included between the fins and the exit; and wherein the spacing is proportionally between about 4 and 5 times larger than the exit diameter.

12. A system according to claim 1 further comprising a filtration system.

13. A system according to claim 12 wherein the filtration system includes a filter adjacent to the fluid flow generator that filters contaminants from the fluid.

14. A system according to claim 1 wherein the flow direction of the fluid is intermittently reversed.

15. A system according to claim 14 wherein the flow direction is defined by the fluid being received by the input and exhausted by the exit; and
wherein a flow direction that is reversed is defined by the fluid being received by the exit and exhausted by the input.

16. A system according to claim 1 wherein the acoustic baffle members are adjacent to the LEDs.

17. A system according to claim 1 wherein the acoustic baffle members are adjacent to the micro-channel heatsink.

18. A system according to claim 1 wherein the acoustic baffle members are adjacent to an inside surface of a LED bulb holder.

19. A cooling system for light emitting diodes (LEDs), comprising:
a micro-channel heatsink adjacent to the LEDs, the micro-channel heatsink including fins that are each separated by a gap; and
a fluid flow generator adjacent to the micro-channel heatsink that directs a fluid in a flow direction, the fluid flow generator including an input to receive the fluid and an exit to exhaust the fluid as an impinging jet to contact a surface area of the fins, the exhausted fluid creating static pressure to drive the fluid through the micro-channel heatsink.

20. A system according to claim 19 further comprising acoustic baffle members; and wherein sound emitted by the fluid flow generator is substantially cancelled by the acoustic baffle members.

21. A system according to claim 20 wherein the sound includes source sound waves defined by a source phase; and wherein the acoustic baffle members reflect the sound to a source location as reflected sound waves defined by a reflected phase.

22. A system according to claim 21 wherein the reflected phase is substantially inverted from the source phase; and wherein combining the source sound waves and the reflected sound waves substantially cancels the sound emitted from the fluid flow generator.

23. A system according to claim 21 wherein the source sound waves originate from the source location being proximately located to the exit of the fluid flow generator.

24. A system according to claim 19 wherein the fluid is gaseous.

25. A system according to claim 19 wherein the fluid flow generator is a piezoelectric diaphragm driving device.

26. A system according to claim 19 wherein the gap is further defined as having a width between about 0.1 millimeters and 4 millimeters.

27. A system according to claim 19 wherein the fins are curved.

28. A system according to claim 19 wherein the exit is defined by an exit diameter; wherein a spacing is included between the fins and the exit; and wherein the spacing is proportionally between about 4 and 5 times larger than the exit diameter.

29. A system according to claim 19 further comprising a filtration system.

30. A system according to claim 20 wherein the filtration system includes a filter adjacent to the fluid flow generator that traps contaminants.

31. A system according to claim 19 wherein the flow direction of the fluid is intermittently reversed.

32. A system according to claim 31 wherein the flow direction is defined by the fluid being received by the input and exhausted by the exit; and wherein a flow direction that is reversed is defined by the fluid being received by the exit and exhausted by the input.

33. A system according to claim 20 wherein the acoustic baffle members are adjacent to the LEDs.

34. A system according to claim 20 wherein the acoustic baffle members are adjacent to the micro-channel heatsink.

35. A system according to claim 20 wherein the acoustic baffle members are adjacent to an inside surface of a LED bulb holder.

36. A method of cooling light emitting diodes (LEDs) using an active cooling system that includes acoustic baffle members, a micro-channel heatsink having fins, and a fluid flow generator having an input and an exit, the method comprising:
exhausting fluid from the exit in a flow direction to contact the fins;
substantially canceling sound emitted by the fluid flow generator by reflecting source sound waves to a source location as reflected sound waves so that the source sound waves are combined with the reflected sound waves, the source sound waves defined by a source phase and the reflected sound waves defined by a reflected phase, the reflected phase being substantially inverted from the source phase.

37. A method according to claim 36 wherein the source sound waves originate from the source location being proximately located to the exit of the fluid flow generator.

38. A method according to claim 36 wherein the step of exhausting the fluid further comprises exhausting the fluid as an impinging jet.

39. A method according to claim 38 wherein the impinging jet creates static pressure to drive the fluid through the micro-channel heatsink.

40. A method according to claim 36 wherein the fluid is gaseous.

41. A method according to claim 36 wherein the fluid flow generator is a piezoelectric diaphragm driving device.

42. A method according to claim 36 wherein the fins of the micro-channel heatsink are each separated by a gap having a width between about 0.1 millimeters and 4 millimeters.

43. A method according to claim 36 wherein the fins are curved.

44. A method according to claim 36 wherein the exit is defined by an exit diameter; wherein a spacing is included between the fins and the exit;
and wherein the spacing is proportionally between about 4 and 5 times larger than the opening diameter.

45. A method according to claim 36 further comprising filtering contaminates from the fluid.

46. A method according to claim 45 further comprising passing the fluid through a filter adjacent to the fluid flow generator that filters the contaminants.

47. A method according to claim 36 further comprising intermittently reversing the flow direction of the fluid.

48. A method according to claim 36 wherein the flow direction is defined by the fluid being received by the input and exhausted by the exit; and
wherein a fluid direction that is reversed is defined by the fluid being received by the exit and exhausted by the input.

49. A method according to claim 36 wherein the acoustic baffle members are adjacent to the LEDs.

50. A method according to claim 36 wherein the acoustic baffle members are adjacent to the micro-channel heatsink.

51. A method according to claim 36 wherein the acoustic baffle members are adjacent to an inside surface of a LED bulb holder.
